(19) United States
(12) Patent Application Publication
(10) Pub. No.: US 2026/0099094 A1
(43) Pub. Date: Apr. 9, 2026

(54) Photoresist coating method

(71) Applicant: United Semiconductor(Xiamen)Co., Ltd., Xiamen (CN)

(72) Inventors: Cheng Qun Fang, Datian County (CN); XIONGWU HE, shamen City (CN); QingZhang Zhang, Shamen City (CN); WEN YI TAN, xiamen (CN)

(73) Assignee: United Semiconductor(Xiamen)Co., Ltd., Xiamen (CN)

(21) Appl. No.: 18/931,015

(22) Filed: Oct. 29, 2024

(30) Foreign Application Priority Data
Oct. 9, 2024 (CN) 202411401089.2

(51) Int. Cl. G03F 7/16

(52) U.S. Cl. CPC G03F 7/162; G03F 7/168

(57) ABSTRACT

The invention provides a photoresist coating method, which comprises the following steps: providing a wafer, keeping the wafer at a first rotation speed, spraying a photoresist on a surface of the wafer, performing a high rotation speed step, increasing the rotation speed of the wafer to a second rotation speed, and moving part of the photoresist to an edge region on the wafer, performing a first wafer edge cleaning step on the edge region of the wafer, reducing the rotation speed of the wafer to a third rotation speed, and performing a second wafer edge cleaning step on the edge region of the wafer.

### BACKGROUND OF THE INVENTION

### 1. Field of the Invention

The invention relates to the field of semiconductor process, in particular to a photoresist coating method, which is helpful to improve the uniformity of photoresist coating and the quality of wafer edge after photoresist coating.

### 2. Description of the Prior Art

Photoresist coating is one of the commonly used technologies in semiconductor manufacturing. When it is necessary to form the required pattern on the material layer, it is necessary to use a photomask to perform lithography steps (including photoresist coating, exposure, development, etching, etc.). Therefore, the uniformity of photoresist coating will obviously affect the yield of semiconductor manufacturing process. For example, when the surface of some material layers has a special shape, it is not easy for photoresist to cover the whole wafer completely during spin coating. If some wafers are not covered with photoresist, subsequent patterns cannot be formed at this position, which has a great impact on the yield of semiconductor manufacturing.

In order to make the photoresist cover the whole wafer as much as possible, in the photoresist coating step, more photoresist is often used for coating, so as to avoid that the whole wafer cannot be covered because the amount of photoresist is too small. However, if too much photoresist is coated on the surface of the wafer, it may also cause some problems in the process. For example, when the photoresist is dispersed to the edge by spin coating, excess photoresist may accumulate at the edge of the wafer, and these accumulated photoresists are not easy to be cleaned in the process because of their large volume, so the photoresist may be stacked in the edge region of the wafer, which may affect the subsequent semiconductor device process.

### SUMMARY OF THE INVENTION

The invention provides a photoresist coating method, which comprises the following steps: providing a wafer, keeping the wafer at a first rotation speed, spraying a photoresist on a surface of the wafer, carrying out a high rotation speed step, raising the rotation speed of the wafer to a second rotation speed, moving part of the photoresist to an edge region on the wafer, carrying out a first wafer edge cleaning step on the edge region of the wafer, reducing the rotation speed of the wafer to a third rotation speed, and carrying out a second wafer edge cleaning step on the edge region of the wafer.

The applicant found that in the photoresist coating method in the prior art, when the photoresist is excessively thick, it will cause the photoresist to accumulate at the wafer edge, and because there is a long time (about 1 minute or more) between the photoresist coating step and the wafer edge cleaning step, the photoresist accumulated at the wafer edge is usually dried and hardened, which makes it difficult for the wafer edge cleaning step to completely remove the photoresist accumulated at the wafer edge. Therefore, the present invention provides a photoresist coating method. Compared with the conventional photoresist coating step, two additional steps are inserted in the photoresist spin coating process, namely, firstly, most photoresist is rotationally dispersed to the edge of the wafer at a high speed rotation, and then, a pre-cleaning step is used to clean the edge of the wafer before the photoresist is hardened. In this way, when the second wafer edge cleaning step is performed, the photoresist remaining at the wafer edge can be easily removed. Therefore, the invention has the advantage of improving the quality of semiconductor elements.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIGS. 1 to 6 show a schematic diagram of a wafer structure and an enlarged schematic diagram of a wafer section coated with photoresist according to an embodiment of the present invention, wherein:

FIG. 1 shows a schematic diagram of coating a solvent on a wafer;

FIG. 2 shows a schematic diagram of coating photoresist on a wafer and mixing photoresist with the solvent, and an enlarged view of part of the wafer surface;

FIG. 5 is a schematic diagram showing the step of performing a high rotation speed and an enlarged view of part of the wafer surface;

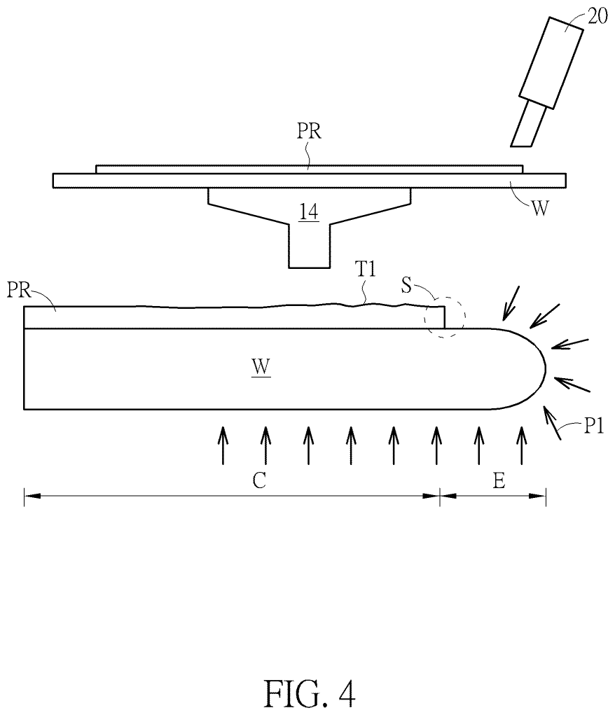

FIG. 4 shows a schematic diagram showing the step of performing a first wafer edge cleaning step and an enlarged view of part of the wafer surface;

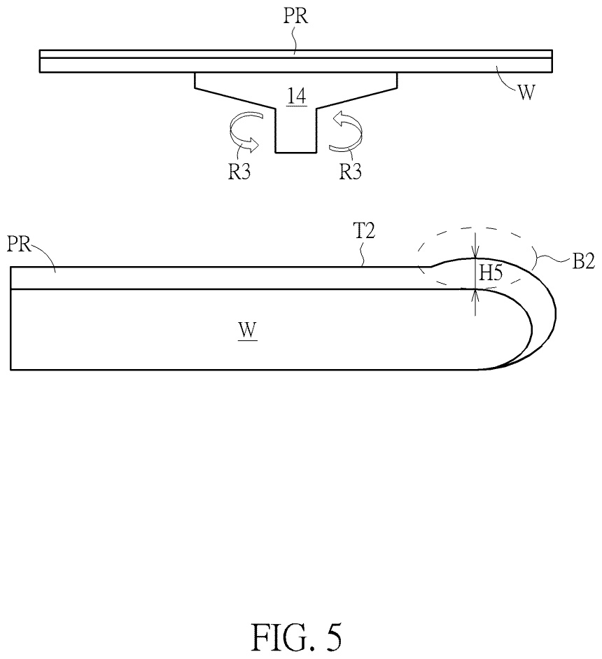

FIG. 5 is a schematic diagram showing the step of performing a medium rotation speed and an enlarged view of part of the wafer surface; and

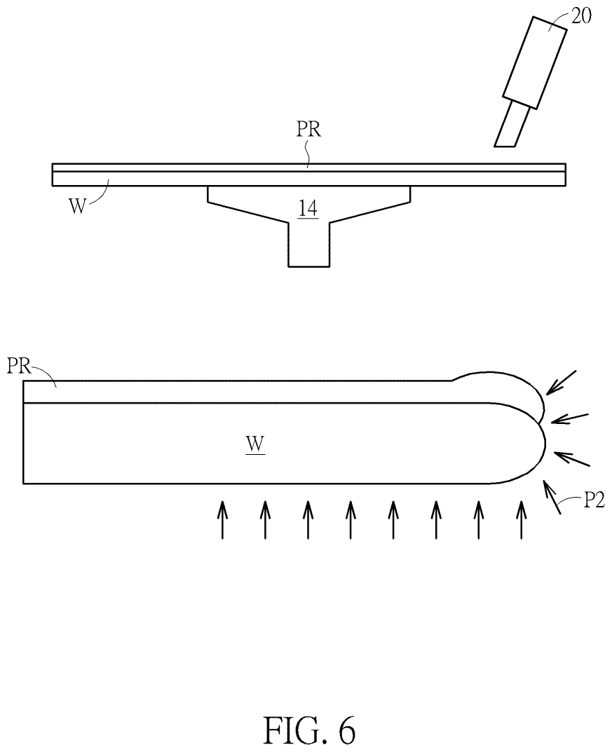

FIG. 6 shows a schematic diagram showing the step of performing a second wafer edge cleaning step and an enlarged view of part of the wafer surface.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

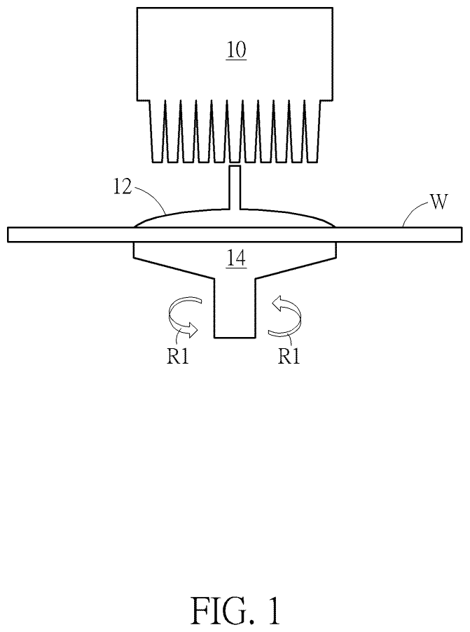

Please refer to FIGS. 1 to 6, which show schematic cross-sectional structures of coating photoresist on a wafer according to an embodiment of the present invention, wherein FIG. 1 shows schematic diagrams of coating a solvent on the wafer. First, a wafer W is provided, for example, a silicon wafer, or other various wafers such as gallium nitride, silicon carbide, silicon-on-insulator (SOI), and the present invention is not limited to this. A nozzle 10 sprays a solvent 12 onto the wafer W. The nozzle 10 described here is used to spray various material layers, such as the solvent here or the subsequent photoresist, onto the surface of the wafer W, and the solvent 12 is used to dissolve the subsequent photoresist and wet the wafer W in advance, so that the subsequent photoresist can be dissolved in the solvent and better dispersed throughout the wafer W during the spin coating step. Generally speaking, the solvent 12 is, for example, propylene glycol monomethyl ether (PGME), which is a common photoresist solvent and has good solubility, volatility and stability, or propylene glycol monomethyl ether acetate (PGMEA), which has high solubility and can be used to dissolve high molecular weight photoresist. However, the above solvents are just some examples, and the present invention is not limited thereto.

In addition, the wafer W is located on a spin coater 14, which contains a rotatable motor. The wafer W is placed on the spin coater 14, and then the spin coater 14 can rotate and drive the wafer W, so that the solution on the surface of the wafer W (such as the above-mentioned solvent 12) spreads outward by centrifugal force and is coated on the entire surface of the wafer W. Other related knowledge about the spin coater 14 belongs to the conventional technology in the field, and will not be introduced here.

As shown in FIG. 1, in this embodiment, after the solvent 12 is sprayed on the surface of the wafer W, the rotation step is performed at a rotation speed of about 700 RPM for about 10 seconds. Here, for convenience of distinction, 700 RPM is defined as the first rotation speed R1. The purpose of the rotating step described here is to disperse the solvent 12 onto the surface of the wafer W, so as to achieve the effect of pre-wetting the surface of the wafer W.

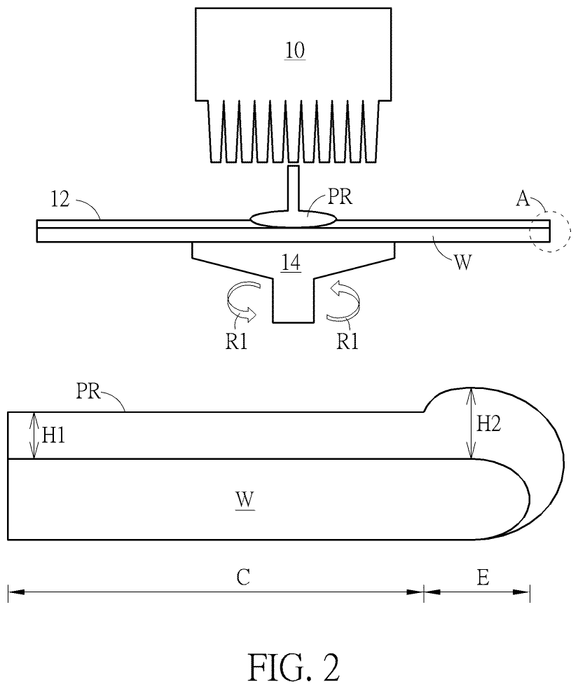

FIG. 2 shows a schematic diagram of coating photoresist on a wafer and mixing photoresist with a solvent, and an enlarged view of part of the wafer surface. As shown in FIG. 2, the nozzle 10 sprays a photoresist PR onto the surface of the wafer W. Photoresist PR is a common photoresist material in semiconductor manufacturing, such as positive photoresist and negative photoresist. In terms of materials, the common photoresist materials may include phenolic resin photoresist, which is the most commonly used photoresist material with good comprehensive performance, and can be used to manufacture various integrated circuits, the photoresist may also include acrylate photoresists, which have high photosensitivity and high resolution, can be used to manufacture high-precision circuits, or the photoresist may include epoxy resin photoresists, it has good chemical resistance and can be used to manufacture thick-film circuits. But the present invention is not limited thereto.

After the photoresist PR is sprayed on the surface of the wafer W, it will be mixed with the solvent 12 to improve the fluidity of the photoresist PR. In other words, the photoresist PR mixed with the solvent 12 is more easily diffused to the edge of the wafer W in spin coating.

As mentioned above, in order to avoid uneven coating of photoresist, when spraying photoresist PR on the surface of wafer W, it prefers to spray more photoresist on the surface of wafer W. When the rotating speed is about 700 RPM, the thickness H1 of photoresist PR in the central region C of wafer W is about 2000 angstroms from the cross-sectional view, as shown in the enlarged view at the lower portion of FIG. 2, which shows the enlarged structural diagram of region A. However, due to the large amount of photoresists PR, most photoresists PR will diffuse to the edge and then accumulate in the edge region E during the spin coating process. As shown in FIG. 2, the thickness H2 of the photoresist PR in the edge region E of the wafer W is about 4000 angstroms or more.

According to the applicant's experiment, if the general subsequent steps are directly carried out after the steps shown in FIG. 2, that is, increasing the rotation speed to reduce the film thickness of the photoresist PR until the required film thickness is reached, and then the wafer edge cleaning step is carried out, the above flow steps will lead to a problem, that is, part of the remaining photoresist PR is easily left in the edge region E of the wafer W. The main reason why the photoresist remains in the edge region E of the wafer W is that the photoresist PR has a large thickness when it is formed, that is to say, more photoresist PR is sprayed on the surface of the wafer W, and in order to reduce the film thickness, it is necessary to gradually increase the rotation speed of the spin coater 14 to slowly reduce the film thickness of the photoresist PR until the required thickness, and then the edge cleaning step of the wafer W is carried out. However, the applicant found that the above steps took a long time, and in order to maintain the flatness of the photoresist film surface, it was necessary to slowly increase the rotation speed of the spin coater 14 (according to the existing process, it was necessary to slowly increase the rotation speed to about 1500 RPM), but this prolonged the spin coating time (the total time was more than 30 seconds). According to the observation results of the applicant, if a large amount of photoresists PR are accumulated in the edge region E of the wafer W, when the time exceeds one minute, these photoresists PR will gradually start to dry and harden, resulting in difficulties in the subsequent cleaning step. However, if these photoresists PR accumulated in the edge region E of the wafer W are not cleaned, it will have an impact on the subsequent semiconductor process, such as peeling in the edge region E.

However, according to the above steps, if just simply increasing the rotation speed rapidly (for example, directly increasing it to more than 2500 RPM) to shorten the time required for reducing the film thickness, it will cause another problem, that is, it is not easy to form a flat surface of the photoresist film under the condition of rapidly increasing the rotation speed. Therefore, according to the conventional steps, when the photoresist PR is coated on the surface of the wafer W, no matter whether the rotation speed is high or low, it will cause corresponding shortcomings.

In the current process, after the photoresist PR is sprayed, the rotation speed is increased to about 1700 to 2000 RPM, and the rotation is carried out for about 15 seconds or more, so as to gradually reduce the thickness of the photoresist PR to the required thickness. However, as mentioned above, although the top surface of the photoresist PR after spin coating can be kept flat at such a rotation speed and time, the photoresist PR is easy to accumulate in the edge region E of the wafer W due to drying and hardening.

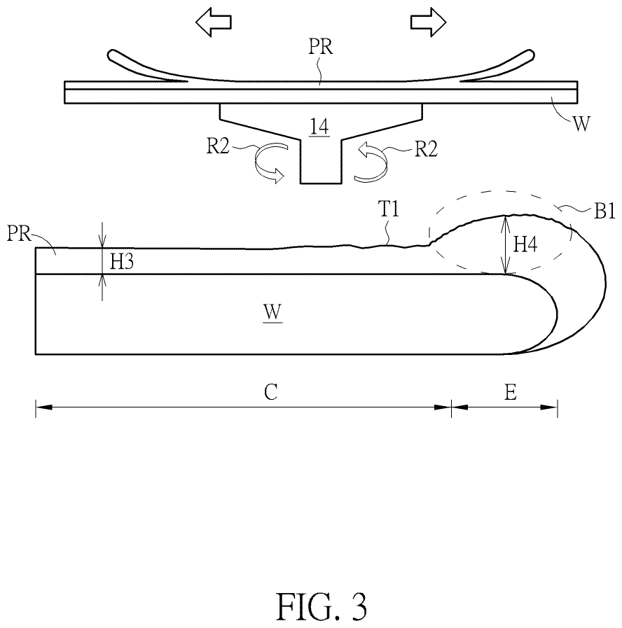

Therefore, in order to improve the disadvantages caused by the above steps, the present invention provides an improved photoresist coating step. Please continue to refer to FIG. 3, which shows a schematic diagram of a high speed step and an enlarged view of part of the wafer surface. Here, FIG. 3 continues the steps of FIG. 2. As shown in FIGS. 2 and 3, the rotation speed of the spin coater 14 is increased to a second rotation speed R2, which is higher than the first rotation speed R1. Taking this embodiment as an example, in the process of spraying photoresist PR shown in FIG. 2, the rotation speed is increased to the second rotation speed R2, which is about 2800 RPM and lasts for about 1 to 3 seconds. It is worth noting that the second rotation speed R2 described here is higher than that in the conventional steps (for example, in the currently process, the rotation speed is about 1700 RPM to 2000 RPM), and the rotation time is also shorter. When the rotation speed is increased to the second rotation speed R2, most of the photoresist PR can be thrown out of the wafer W or dispersed to the edge region E of the wafer W by high centrifugal force, while some photoresist PR is moved to the edge region E to accumulate and produce a bump B1. In addition, because the second rotation speed R2 is relatively high, an uneven surface T1 may be generated on the surface of the photoresist PR under high-speed rotation. Especially closer to the edge region E. Here, the second rotation speed R2 and the continuous rotation time can be adjusted as required, but it is worth noting that it is necessary to control the second rotation speed R2 and the time, so that the film thickness of the photoresist PR can be quickly reduced to a height higher than the required film thickness. For example, assuming that the film thickness of the photoresist PR that is finally needed is 400 angstroms, the thickness H3 of the photoresist PR should be set to be greater than 400 angstroms, for example, about 500 angstroms, after the rotation speed is increased to the second rotation speed R2 here for a set time. The purpose of setting the film thickness of the photoresist PR to be greater than the final required film thickness is that the surface of the photoresist PR is not easy to remain flat under high-speed rotation, for example, the surface T1 of this embodiment is an uneven surface, so some thickness of the photoresist PR is reserved, and the surface of the photoresist PR will become more flat at a moderate rotation speed in the following steps.

In addition, it is worth noting that increasing the rotation speed to the second rotation speed R2 is helpful to quickly reduce the film thickness of photoresist PR, which means that the time spent in the spin coating process can be reduced. Next, please refer to FIG. 4, which shows a schematic diagram of the first wafer edge cleaning step and an enlarged view of part of the wafer surface. As shown in FIG. 4, a cleaning nozzle 20 is used to perform a first wafer edge cleaning step P1, such as a rinsing step, to remove the accumulated photoresist PR in the edge region E of the wafer W. Since the film thickness of the photoresist PR has been rapidly reduced in the above-mentioned step of FIG. 3, the photoresist PR is still in a flowable state when the wafer edge cleaning step P1 of FIG. 4 is performed immediately, that is to say, the photoresist PR has not been dried and hardened, and the efficiency of the first wafer edge cleaning step P1 can be improved. After the first wafer edge cleaning step P1, the accumulated photoresist PR in the edge region E of the wafer W is completely removed, and the surface of the wafer W is exposed.

According to the applicant's experiment, it takes about 10 seconds from raising the rotation speed to the second rotation speed shown in FIG. 3 to the first wafer edge cleaning step P1 shown in FIG. 4. That is to say, the photoresist PR is still in a flowable state at this time, and has not yet started to dry and harden. Therefore, by performing the first wafer edge cleaning step P1, most of the photoresist PR remaining in the edge region E of the wafer W can be removed first, leaving only a small amount of photoresist PR on the surface of the wafer W, so that the problem that peeling is easy to occur in the subsequent period due to excessive photoresist PR accumulation at the wafer edge can be avoided.

In addition, in this step, the surface T1 of the photoresist PR is still an uneven surface, and the spin coating will be continued in the subsequent step to reshape the photoresist PR into a layer structure with a flat surface.

Subsequently, please refer to FIGS. 5 and 6. FIG. 5 shows a schematic diagram of performing a middle rotation speed step and an enlarged view of part of the wafer surface, and FIG. 6 shows a schematic diagram of a second wafer edge cleaning step and an enlarged view of part of the wafer surface. As shown in FIG. 5, the rotation speed is reduced to a third rotation speed R3, and the photoresist PR in the central region C of the wafer W is diffused into the edge region E again. The third rotation speed R3 mentioned here is lower than the second rotation speed R2. Taking this embodiment as an example, the third rotation speed R3 is about 1100 RPM, and the rotation time maintained in the third rotation speed R3 is about 13 seconds to 20 seconds, but the present invention is not limited to this. The third rotation speed R3 is lower than the second rotation speed R2, so the film thickness of the photoresist PR can be slowly decreased and diffused again, but the decreasing speed of the photoresist film thickness will be more moderate than the step shown in FIG. 3, so the surface of the photoresist PR can be made flatter. That is, during the rotation at the third rotation speed R3, the surface of the photoresist PR will become flatter, as shown in the surface T2 in FIG. 5.

In addition, in the process of rotating at the third rotation speed R3, a part of the photoresist PR will still be thrown to the edge region E of the wafer W by centrifugal force. However, since the high-speed rotation (i.e. the second rotation speed R2) and the first wafer edge cleaning step P1 have been carried out in the above steps, most of the photoresist PR stacked in the edge region E has been removed first, so even if a small amount of photoresist PR moves to the edge region E and accumulates, the thickness of the generated bump B2 will be obviously smaller than that of the bump B1 in FIG. 3. Taking this embodiment as an example, the thickness of the highest point H4 of the bump B1 shown in FIG. 3 is about 5500 angstroms, while the thickness of the highest point H5 of the bump B2 shown in FIG. 5 is about 1100 angstroms.

Next, as shown in FIG. 6, a second wafer edge cleaning step P2 is performed. The second wafer edge cleaning step P2 described here is similar to the first wafer edge cleaning step P1 described above, and the solvent (such as acetone and isopropanol) that can remove photoresist is also sprayed by the cleaning nozzle 20 to remove photoresist. Since most of the photoresists have been removed in the above-mentioned step in FIG. 4, even though the photoresists PR in the edge region E have started to dry and harden, they can still be easily removed by the second wafer edge cleaning step P2 because of their low thickness.

Subsequently, other semiconductor processes will be carried out, such as patterning the photoresist and forming various required electronic components. These steps belong to the known technology in this field, and will not be repeated here.

In the conventional technologies, a wafer edge cleaning step is usually performed only after the film thickness of the photoresist is reduced to the required thickness, so as to remove the photoresist residue at the wafer edge and prevent the photoresist residue from affecting the subsequent process. However, when the thickness of photoresist is large, it is easy to leave photoresist on the wafer edge by only one wafer edge cleaning step. Compared with the prior art, the present invention firstly moves most of the photoresist to the wafer edge or throws the wafer at a high rotation speed (second rotation speed R2), and then carries out the first wafer edge cleaning step P1 before the photoresist is dried. Then, the film thickness of the photoresist is reduced to the required height at the middle and low rotation speed (the third rotation speed R3), and the second wafer edge cleaning step P2 is performed. Therefore, the wafer edge cleaning step is carried out twice in total, so that the quality of the wafer edge can be greatly improved, and the peeling phenomenon caused by residual photoresist on the wafer edge in subsequent steps can be reduced. According to the experimental results of the applicant, after using the method of the invention, the probability of wafer edge peeling in the subsequent process is reduced from about 1.38% to 0.05%, that is to say, compared with the conventional steps, the probability of wafer peeling issues in the steps of the invention is only about 1/27 of the original.

Based on the above description and drawings, the present invention provides a photoresist coating method, which includes providing a wafer W, maintaining the wafer at a first rotation speed R1 (as shown in FIG. 1), spraying a photoresist PR on a surface of the wafer W, performing a high rotation speed step to increase the rotation speed of the wafer to a second rotation speed R2 (as shown in FIG. 2-3), and moving part of the photoresist PR to an edge region E on the wafer W. After the above steps, a first wafer edge cleaning step P1 is performed on the edge region E of the wafer W, after the above steps, the rotation speed of the wafer W is reduced to a third rotation speed R3 (as shown in FIG. 5), and after the above steps, a second wafer edge cleaning step P2 is performed on the edge region E of the wafer W.

In some embodiments of the present invention, the first wafer edge cleaning step P1 is performed within 10 seconds after the rotation speed of the wafer W is increased to the second rotation speed (that is, the first wafer edge cleaning step P1 of FIG. 4 is performed within 10 seconds after the step of FIG. 3).

In some embodiments of the present invention, after the first wafer edge cleaning step P1, the rotation speed is reduced to the third rotation speed R3 and maintained at the third rotation speed for more than 10 seconds (as shown in FIG. 5).

In some embodiments of the present invention, after the rotation speed of the wafer W is increased to the second rotation speed R2, a photoresist bump B1 is formed in the edge region E of the wafer.

In some embodiments of the present invention, the photoresist bump B1 is removed after the first wafer edge cleaning step P1.

In some embodiments of the present invention, when the first wafer edge cleaning step P1 is performed, the photoresist PR is in a flowable state (that is, the photoresist PR at this time has not been dried, so it is easy to be removed).

In some embodiments of the present invention, during the second wafer edge cleaning step P2, the photoresist is in a dry state (although the photoresist has been dried at this time, it can still be removed because of its small thickness).

In some embodiments of the present invention, a solvent 12 is sprayed on the wafer W before the photoresist PR is sprayed on the wafer W, and then the photoresist PR is sprayed and dissolved in the solvent 12.

In some embodiments of the present invention, before the first wafer edge cleaning step P1 is performed, one side surface in the edge region E of the wafer W is covered by the photoresist PR (that is, the top surface and part of the side walls of the wafer W are covered by the photoresist PR in cross section).

In some embodiments of the present invention, after the first wafer edge cleaning step P1 is completed, the side surface in the edge region E of the wafer W is exposed.

In some embodiments of the present invention, the first rotation speed R1 is between 500 RPM and 1000 RPM, the second rotation speed R2 is between 2500 RPM and 3500 RPM, and the third rotation speed R3 is between 800 RPM and 1200 RPM.

In some embodiments of the present invention, when the wafer W is maintained at the first rotation speed R1, the thickness of the photoresist PR is between 1700 angstroms and 2300 angstroms.

In some embodiments of the present invention, the thickness of the photoresist is between 400 angstroms and 600 angstroms when the wafer is maintained at the second rotation speed R2.

In some embodiments of the present invention, when the wafer is maintained at the third rotation speed R3, the thickness of the photoresist is between 300 angstroms and 500 angstroms, and the thickness of the photoresist PR is smaller than that of the photoresist PR when the wafer W is maintained at the second rotation speed R2.

In some embodiments of the present invention, after the first wafer edge cleaning step P1 is completed, a central region C of the wafer is covered with photoresist PR, and the photoresist in the central region C has an uneven surface T1. As described above, since the second rotation speed R2 is relatively fast, an uneven surface T1 is formed on the surface of the photoresist PR.

In some embodiments of the present invention, after the first wafer edge cleaning step P1 is completed, an interface between the central region C and the edge region E of the wafer has a stepped cross-sectional structure (refer to FIG. 4, there is a difference S between the photoresist PR in the central region C and the edge region E).

In some embodiments of the present invention, the wafer W contains a pattern (for example, some circuit patterns formed in the device region), wherein the pattern is located in the central region C but not in the edge region E.

In some embodiments of the present invention, after the second wafer edge cleaning step P2 is completed, a central region C and an edge region E of the wafer are covered with photoresist PR, and the photoresist PR of the central region C and the edge region E has a flat surface T2.

To sum up, the applicant found that in the photoresist coating method in the prior art, too thick photoresist will accumulate at the wafer edge when spin coating, and because there is a long time (about 1 minute or more) between the photoresist coating step and the wafer edge cleaning step, the photoresist accumulated at the wafer edge is usually dried and hardened, which makes it difficult for the wafer edge cleaning step to completely remove the photoresist accumulated at the wafer edge. Therefore, the present invention provides a photoresist coating method. Compared with the conventional photoresist coating step, two additional steps are inserted in the photoresist spin coating process, namely, firstly, most photoresist is rotationally dispersed to the wafer edge at a high rotation speed, and then a pre-cleaning step (the first wafer cleaning step) is used to clean the wafer edge before the photoresist is hardened. In this way, when the wafer edge is cleaned for the second time, the photoresist remaining at the wafer edge can be easily removed. Therefore, the invention has the advantage of improving the quality of semiconductor elements.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A photoresist coating method, characterized in that:
providing a wafer to maintain in a first rotation speed;
spraying a photoresist on a surface of the wafer;
performing a high rotation speed step to increase the rotation speed of the wafer to a second rotation speed, and moving part of the photoresist to an edge region on the wafer;
performing a first wafer edge cleaning step on the edge region of the wafer after the above steps are performed;
reducing the rotation speed of the wafer to a third rotation speed after the above steps are performed; and
performing a second wafer edge cleaning step on the edge region of the wafer after the above steps are performed.

2. The photoresist coating method according to claim 1, wherein the first wafer edge cleaning step is performed within 10 seconds after the rotation speed of the wafer is increased to the second rotation speed.

3. The photoresist coating method according to claim 1, wherein after the first wafer edge cleaning step, the rotation speed is reduced to the third rotation speed and maintained at the third rotation speed for more than 10 seconds.

4. The photoresist coating method according to claim 1, wherein a photoresist bump is formed in the edge region of the wafer after the rotation speed of the wafer is increased to the second rotation speed.

5. The photoresist coating method according to claim 4, wherein the photoresist bump is removed after the first wafer edge cleaning step.

6. The photoresist coating method according to claim 1, wherein the photoresist is in a flowable state when the first wafer edge cleaning step is performed.

7. The photoresist coating method according to claim 1, wherein the photoresist is in a dry state during the second wafer edge cleaning step.

8. The photoresist coating method according to claim 1, wherein before spraying the photoresist on the wafer, a solvent is sprayed on the wafer, and then the photoresist is sprayed and dissolved in the solvent.

9. The photoresist coating method according to claim 1, wherein before the first wafer edge cleaning step, one side surface of the wafer in the edge region is covered by the photoresist.

10. The photoresist coating method according to claim 9, wherein after the first wafer edge cleaning step is completed, the side surface in the edge region of the wafer is exposed.

11. The photoresist coating method according to claim 1, wherein the first rotation speed is between 500 RPM and 1000 RPM, the second rotation speed is between 2500 RPM and 3500 RPM, and the third rotation speed is between 800 RPM and 1200 RPM.

12. The photoresist coating method according to claim 1, wherein when the wafer is maintained at the first rotation speed, a thickness of the photoresist is between 1700 angstroms and 2300 angstroms.

13. The photoresist coating method according to claim 1, wherein when the wafer is maintained at the second rotation speed, a thickness of the photoresist is between 400 angstroms and 600 angstroms.

14. The photoresist coating method according to claim 13, wherein when the wafer is maintained at the third rotation speed, a thickness of the photoresist is between 300 angstroms and 500 angstroms, and at this time, the thickness of the photoresist is smaller than the thickness of the photoresist when the wafer is maintained at the second rotation speed.

15. The photoresist coating method according to claim 1, wherein after the first wafer edge cleaning step is completed, a central region of the wafer is covered with the photoresist, and the photoresist in the central region has an uneven surface.

16. The photoresist coating method according to claim 15, wherein after the first wafer edge cleaning step, an interface between the central region and the edge region of the wafer has a stepped cross-sectional structure.

17. The photoresist coating method according to claim 15, wherein the wafer comprises a pattern, wherein the pattern is located in the central region but not in the edge region.

18. The photoresist coating method according to claim 1, wherein after the second wafer edge cleaning step is completed, a central region and the edge region of the wafer are covered with the photoresist, and the photoresists in the central region and the edge region have a flat surface.
